(19) United States
(12) Patent Application Publication
(10) Pub. No.: US 2016/0104803 A1
(43) Pub. Date: Apr. 14, 2016

(54) DISPLAY SUBSTRATE AND METHOD OF MANUFACTURING THE SAME

(71) Applicant: Samsung Display Co., LTD., Yongin-City (KR)

(72) Inventors: Tae-Young AHN, Suwon-si (KR); Ji-Hoon OH, Daegu (KR)

(21) Appl. No.: 14/702,479

(22) Filed: May 1, 2015

(30) Foreign Application Priority Data
Oct. 14, 2014 (KR) 10-2014-0138569

(51) Int. Cl. H01L 29/786; H01L 27/12

(52) U.S. Cl. CPC H01L 29/78696; H01L 27/1222; H01L 27/127; H01L 29/78669; H01L 29/78618

(57) ABSTRACT

A display substrate includes a base substrate, a gate pattern, an active pattern and a data metal pattern. The gate pattern includes a gate electrode on the base substrate. The active pattern overlaps the gate electrode and includes a first active layer, a second active layer and a third active layer. The first active layer includes first amorphous silicon (a-Si:H). The second active layer is disposed on the first active layer and includes second amorphous silicon of which a concentration of hydrogen is higher than that of the first amorphous silicon. The third active layer is disposed on the second active layer and includes third amorphous silicon of which a concentration of hydrogen is substantially the same as that of the first amorphous silicon. The data metal pattern is disposed on the active pattern and includes source and drain electrodes spaced apart from each other.

### CROSS-REFERENCE TO RELATED APPLICATION

This application claims priority under 35 USC §119 to Korean Patent Application No. 10-2014-0138569, filed on Oct. 14, 2014 in the Korean Intellectual Property Office (KIPO), the contents of which are herein incorporated by reference in their entirety.

### BACKGROUND

1. Technical Field

Example embodiments relate generally to display apparatuses, and more particularly to display substrates included in display apparatuses and methods of manufacturing the display substrates.

2. Description of the Related Art

A liquid crystal display apparatus is one of a flat panel display (“FPD”), which is used broadly recently. Examples of the FPD include, but are not limited to, a liquid crystal display (“LCD”), a plasma display panel (“PDP”) and an organic light emitting display (“OLED”).

Generally, a display substrate used in a display apparatus includes a thin-film transistor (“TFT”) as a switching element for driving a pixel. The TFT includes a gate electrode connected to a gate line transmitting a gate driving signal, a source electrode connected to a data line transmitting a data driving signal, a drain electrode spaced apart from the source electrode, and an active layer disposed under the source and drain electrodes.

The active layer may include amorphous silicon (a-Si) for reducing manufacturing costs and processes. To improve deposition rate of amorphous silicon, the amount of silane and hydrogen may increase during amorphous silicon is deposited on the substrate. However, amorphous silicon may include silicon dangling bonds, and thus a subthreshold swing of the TFT may be sharply changed.

To remove the silicon dangling bonds in the active layer included in amorphous silicon, the active layer may be annealed in a hydrogen atmosphere using a hydrogen plasma treatment. The silicon dangling bonds in amorphous silicon may be combined with hydrogen by treating amorphous silicon with hydrogen plasma in a relatively low pressure, and thus the silicon dangling bonds may be reduced.

However, since the source and drain electrodes of the TFT are exposed during the hydrogen plasma treatment, and since hydrogen ion has a relatively large kinetic energy due to a relatively small atomic weight, physical damages may occur on the source and drain electrodes and the amorphous silicon layer, and thus a conductive channel in the TFT may have defects.

### SUMMARY

Accordingly, the inventive concept is provided to substantially obviate one or more problems due to limitations and disadvantages of the related art.

Some example embodiments provide a display substrate capable of preventing display defects.

Some example embodiments provide a method of manufacturing the display substrate.

According to example embodiments, a display substrate includes a base substrate, a gate pattern, an active pattern and a data metal pattern. The gate pattern includes a gate electrode on the base substrate. The active pattern overlaps the gate electrode and includes a first active layer, a second active layer and a third active layer. The first active layer includes first amorphous silicon (a-Si:H). The second active layer is disposed on the first active layer, the second active layer including second amorphous silicon of which a concentration of hydrogen is higher than that of the first amorphous silicon. The third active layer is disposed on the second active layer, the third active layer including third amorphous silicon of which a concentration of hydrogen is substantially lower than that of the second active layer. The data metal pattern is disposed on the active pattern and includes source and drain electrodes spaced apart from each other.

The third active layer may be substantially the same as the first active layer.

In an example embodiment, the first amorphous silicon in the first active layer may include Si—H bond.

The second amorphous silicon in the second active layer may include the Si—H bond and Si—H₂ bond.

An amount of the Si—H₂ bond in the second active layer may be about 5 mol % to about 10 mol % of a total mol % of the Si—H bond and the Si—H₂ bond.

In an example embodiment, the first active layer may have a thickness of about 100 Å to about 150 Å.

In an example embodiment, the second active layer may have a thickness of about 1000 Å to about 1500 Å.

In an example embodiment, the third active layer may have a thickness of about 300 Å to about 500 Å.

In an example embodiment, the display substrate may further include an ohmic contact layer. The ohmic contact layer may be disposed on the third active layer and may include impurity-doped silicon.

The impurity-doped silicon may include phosphorous.

According to example embodiments, in a method of manufacturing a display substrate, a gate pattern is formed on a base substrate. The gate pattern includes a gate electrode. An active layer is formed by sequentially depositing a first active layer, a second active layer and a third active layer on the base substrate on which the gate pattern is formed. The first active layer includes first amorphous silicon (a-Si:H). The second active layer is disposed on the first active layer and includes second amorphous silicon of which a concentration of hydrogen is higher than that of the first amorphous silicon. The third active layer is disposed on the second active layer and includes third amorphous silicon of which a concentration of hydrogen is substantially lower than that of the second active layer. An active pattern is formed by patterning the active layer. The third active layer may be substantially the same as the first active layer.

In an example embodiment, the first active layer and the third active layer may be formed by a deposition process using a mixed gas including silane (Si) and hydrogen (H₂). A volume ratio of silane and hydrogen in the mixed gas may be about 1:4 to about 1:5.

The first active layer may have a thickness of about 100 Å to about 150 Å, and the third active layer may have a thickness of about 300 Å to about 500 Å.

The first active layer and the third active layer may have a deposition rate of about 5 Å/sec to about 6 Å/sec.

In an example embodiment, the second active layer may be formed by a deposition process using a mixed gas including silane (Si) and hydrogen (H₂). A volume ratio of silane and hydrogen in the mixed gas may be about 1:6 to about 1:7.

The second amorphous silicon in the second active layer may include Si—H bond and Si—H₂ bond. An amount of the Si—H₂ bond in the second active layer may be about 5 mol % to about 10 mol % of a total mol % of the Si—H bond and the Si—H₂ bond.

The second active layer may have a thickness of about 1000 Å to about 1500 Å.

The second active layer may have a deposition rate of about 20 Å/sec to about 30 Å/sec.

In an example embodiment, an ohmic contact layer including impurity-doped silicon may be formed on the third active layer.

The impurity-doped silicon may include phosphorous.

In an example embodiment, source and drain electrodes spaced apart from each other may be formed on the ohmic contact layer.

Accordingly, in the display substrate and the method of manufacturing the display substrate according to example embodiments, the silicon dangling bonds on the active layer may be effectively reduced, and thus the display defects on the display substrate may be prevented.

### BRIEF DESCRIPTION OF THE DRAWINGS

Illustrative, non-limiting example embodiments will be more clearly understood from the following detailed description taken in conjunction with the accompanying drawings.

FIG. 1 is a plan view illustrating a display substrate according to example embodiments.

FIG. 2 is a plan view illustrating an example of a pixel included in the display substrate of FIG. 1.

FIG. 3 is a cross-sectional view of the display substrate taken along a line I-I′ of FIG. 2.

FIG. 4 is a cross-sectional view illustrating an example of an active pattern included in the display substrate of FIG. 3.

FIGS. 5A, 5B, 5C, 5D and 5E are cross-sectional views for describing a method of manufacturing a display substrate according to example embodiments.

### DETAILED DESCRIPTION OF THE EMBODIMENTS

Various example embodiments will be described more fully with reference to the accompanying drawings, in which embodiments are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present between the element and the other element. In contrast, when an element is referred to as being “directly connected” or “directly coupled” to another element, there are no intervening elements present between the element and the other element. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to limit the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more features, integers, steps, operations, elements, and/or components.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

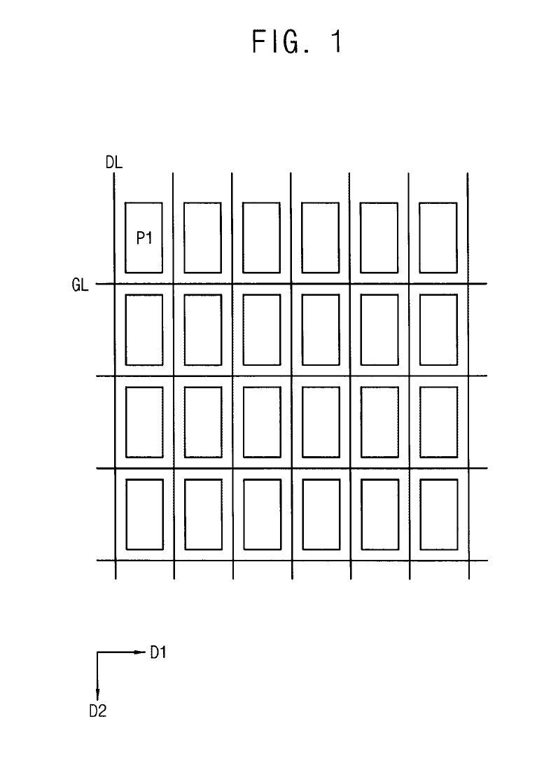

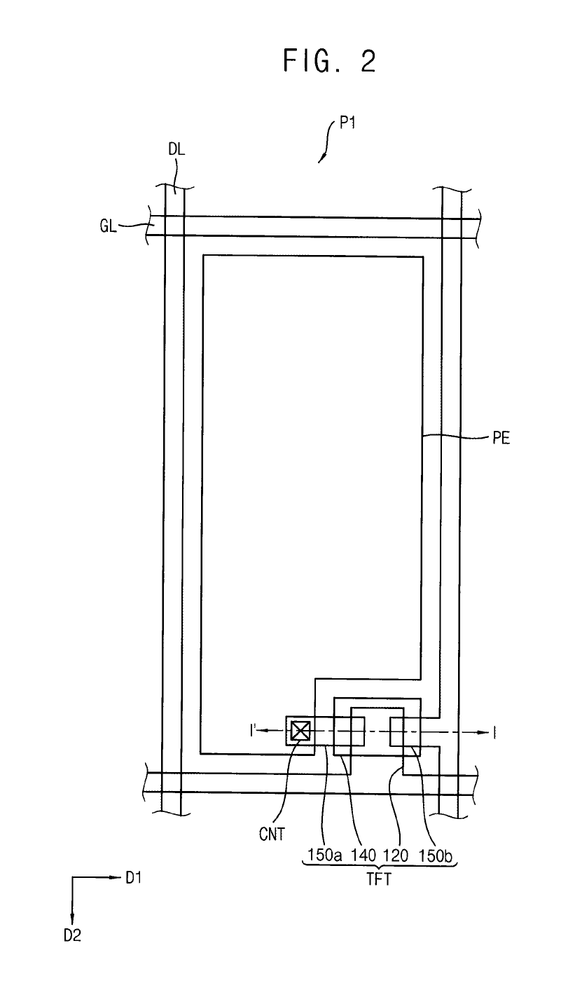

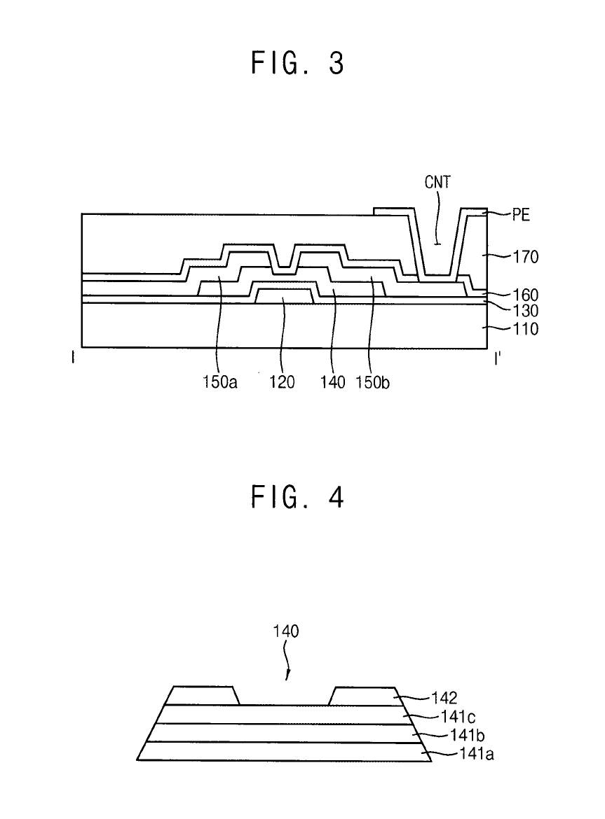

FIG. 1 is a plan view illustrating a display substrate according to example embodiments. FIG. 2 is a plan view illustrating an example of a pixel included in the display substrate of FIG. 1. FIG. 3 is a cross-sectional view of the display substrate taken along a line I-I′ of FIG. 2.

Referring to FIG. 1, a display substrate includes a plurality of gate lines, a plurality of data lines and a plurality of pixels.

The plurality of gate lines may extend in a first direction D1, and the plurality of data lines may extend in a second direction D2 crossing (e.g., substantially perpendicular to) the first direction D1. Alternatively, although not illustrated in FIG. 1, the plurality of gate lines may extend in the second direction D2, and the plurality of data lines may extend in the first direction D1.

The plurality of pixels may be arranged in a matrix form. The plurality of pixels may be disposed in a plurality of pixel areas that are defined by the plurality of gate lines and the plurality of data lines.

Each pixel may be connected to a respective one of the gate lines (e.g., an adjacent one gate line) and a respective one of the data lines (e.g., an adjacent one data line). For example, a first pixel P1 may be connected to a gate line GL and a data line DL. Each pixel may have, but is not limited to, a rectangular shape, a V shape, a Z shape, etc.

Referring to FIGS. 1, 2 and 3, the display substrate includes a base substrate 110, a thin film transistor TFT, an insulation layer 130, a passivation layer 160, a color filter 170 and a pixel electrode PE.

The base substrate 110 may be a transparent substrate that includes insulation material. For example, the base substrate 110 may be a glass substrate or a transparent plastic substrate. The base substrate 110 may include the plurality of pixel areas for displaying an image. The plurality of pixel areas may be arranged in a matrix form.

Each pixel may include a switching element. For example, the thin film transistor TFT may be the switching element. The switching element may be connected to the respective one of the gate lines (e.g., the adjacent one gate line GL) and the respective one of the data lines (e.g., the adjacent one data line DL).

A gate pattern may be disposed on the base substrate 110. The gate pattern may include a gate electrode 120 and the gate line GL. The gate line GL may be electrically connected to the gate electrode GE.

The gate pattern may include a low resistance material. For example, the gate pattern may include aluminum (Al), molybdenum (Mo), titanium (Ti), copper (Cu) or an alloy thereof. The gate pattern may be formed in a single layer or a multi layer.

The insulation layer 130 may be disposed on the base substrate 110 on which the gate pattern is disposed. The insulation layer 130 may cover the gate pattern, and the gate pattern may be insulated by the insulation layer 130.

The insulation layer 130 may include inorganic insulation material. For example, the insulation layer 130 may include silicon oxide (SiO_{X}) and/or silicon nitride (SiN_{X}). For example, the insulation layer 130 may be formed by a sputtering process.

An active pattern 140 may be disposed on the insulation layer 130. The active pattern 140 may overlap the gate electrode 120.

A data metal pattern may be disposed on the insulation layer 130 on which the active pattern 140 is disposed. The data metal pattern may include a source electrode 150a, a drain electrode 150b and the data line DL.

The source electrode 150a may partially overlap the active pattern 140. The source electrode 150a may be electrically connected to the data line DL. The drain electrode 150b may partially overlap the active pattern 140 and may be spaced apart from the source electrode 150a on the active pattern 140. The active pattern 140 may have a conductive channel between the source electrode 150a and the drain electrode 150b.

The thin film transistor TFT may include the gate electrode 120, the source electrode 150a, the drain electrode 150b and the active pattern 140.

A structure of the active pattern 140 will be described below with reference to FIG. 4.

The passivation layer 160 may be disposed on the insulation layer 130 on which the active pattern 140 and the data metal pattern are disposed. The passivation layer 160 may cover the thin film transistor TFT (e.g., the source electrode 150a, the drain electrode 150b and the active pattern 140), and the source electrode 150a, the drain electrode 150b and the active pattern 140 may be protected by the passivation layer 160.

The passivation layer 160 may include inorganic insulation material. For example, the passivation layer 160 may include silicon oxide (SiO_{X}) and/or silicon nitride (SiN_{X}). For example, the passivation layer 160 may be formed by a sputtering process. The passivation layer 160 may include organic insulation material.

The color filter 170 may be disposed on the passivation layer 160.

The color of light may be changed by the color filter 170, and the light may pass through a liquid crystal layer (not illustrates). The color filter 170 may be, but is not limited to, a red color filter, green color filter or a blue color filter.

Each color filter may correspond to a respective one of the pixel areas. Color filters, which are adjacent to each other, may have different colors from each other.

The color filters may overlap on a border between pixel areas adjacent to each other. Alternatively, the color filters may be spaced apart from a border between pixel areas adjacent to each other in the first direction D1. For another example, the color filters may be formed in an island-shape at a corresponding one of the crossing regions of the gate lines and the data lines.

The pixel electrode PE may be disposed on the color filter 170 and may be disposed in each pixel area.

The pixel electrode PE may include transparent conductive material. For example, the pixel electrode PE may include indium tin oxide (ITO), indium zinc oxide (IZO) or aluminum-doped zinc oxide (AZO). For example, the pixel electrode PE may have a slit pattern.

A contact hole CNT may be in the color filter 170 to expose a portion of the drain electrode 150b. The pixel electrode PE may be electrically connected to the drain electrode 150b of the thin film transistor TFT through the contact hole CNT. A grayscale voltage (e.g., a gray level voltage) may be applied to the pixel electrode PE through the thin film transistor TFT.

FIG. 4 is a cross-sectional view illustrating an example of an active pattern included in the display substrate of FIG. 3.

Referring to FIGS. 1, 2, 3 and 4, the active pattern 140 may overlap the gate electrode 120. The active pattern 140 may include a first active layer 141a, a second active layer 141b and a third active layer 141c. The active pattern 140 may further include an ohmic contact layer 142. The active pattern 140 may include amorphous silicon (a-Si:H).

The first active layer 141a may overlap the gate electrode 120 and may include first amorphous silicon. The first amorphous silicon in the first active layer 141a may include Si—H bond. The Si—H bond may represent that one hydrogen element (H) is combined with one silane element (Si).

In some example embodiments, the first active layer 141a may have a thickness of about 100 Å to about 150 Å. If the first active layer 141a has a thickness of less than about 100 Å, it may be difficult to reduce a leakage current from the active pattern 140. If the first active layer 141a has a thickness of more than about 150 Å, a deposition speed for forming the first active layer 141a may decrease, and manufacturing costs may increase.

The second active layer 141b may be disposed on the first active layer 141a and may include second amorphous silicon of which a concentration of hydrogen is higher than that of the first amorphous silicon. The second amorphous silicon in the second active layer 141b may include Si—H bond and Si—H₂ bond. The Si—H₂ bond may represent that two hydrogen elements are combined with one silane element.

In some example embodiments, the amount of the Si—H₂ bond in the second active layer 141b may be about 5 mol % to about 10 mol % based on a total mol of the Si—H bond and the Si—H₂ bond.

In some example embodiments, the second active layer 141b may have a thickness of about 1000 Å to about 1500 Å. If the second active layer 141b has a thickness of less than about 1000 Å, a deposition speed for forming the second active layer 141b may decrease, and manufacturing costs may increase. If the second active layer 141b has a thickness of more than about 1500 Å, it may be difficult to reduce a leakage current from the active pattern 140.

The third active layer 141c may be disposed on the second active layer 141b and may include third amorphous silicon of which a concentration of hydrogen is substantially the same as that of the first amorphous silicon.

In some example embodiments, the third active layer 141c may have a thickness of about 300 Å to about 500 Å. If the third active layer 141c has a thickness of less than about 300 Å, it may be difficult to reduce a leakage current from the active pattern 140. If the third active layer 141c has a thickness of more than about 500 Å, a deposition speed for forming the third active layer 141c may decrease, and manufacturing costs may increase.

The ohmic contact layer 142 may be disposed on the third active layer 141c and may include impurity-doped silicon. For example, the impurity-doped silicon may include phosphorous.

The ohmic contact layer 142 may be disposed under the source and drain electrodes 150a and 150b and may contact with the source and drain electrodes 150a and 150b. The ohmic contact layer 142 may include a first ohmic contact layer and a second ohmic contact layer that are spaced apart from each other on the third active layer 141c. The first ohmic contact layer may be disposed under the source electrode 150a, and the second ohmic contact layer may be disposed under the drain electrode 150b.

In some example embodiments, the ohmic contact layer 142 may have a thickness of about 300 Å to about 500 Å.

In the display substrate according to example embodiments, the active pattern 140 may include the first active layer 141a, the second active layer 141b, the third active layer 141c and the ohmic contact layer 142, and thus a hydrogen plasma treatment for the active pattern 140 may be omitted. Thus, physical damages on the source and drain electrodes 150a and 150b and the amorphous silicon layer (e.g., the active pattern 140) due to hydrogen plasma treatment may be prevented, and defects on the conductive channel in the TFT may be prevented.

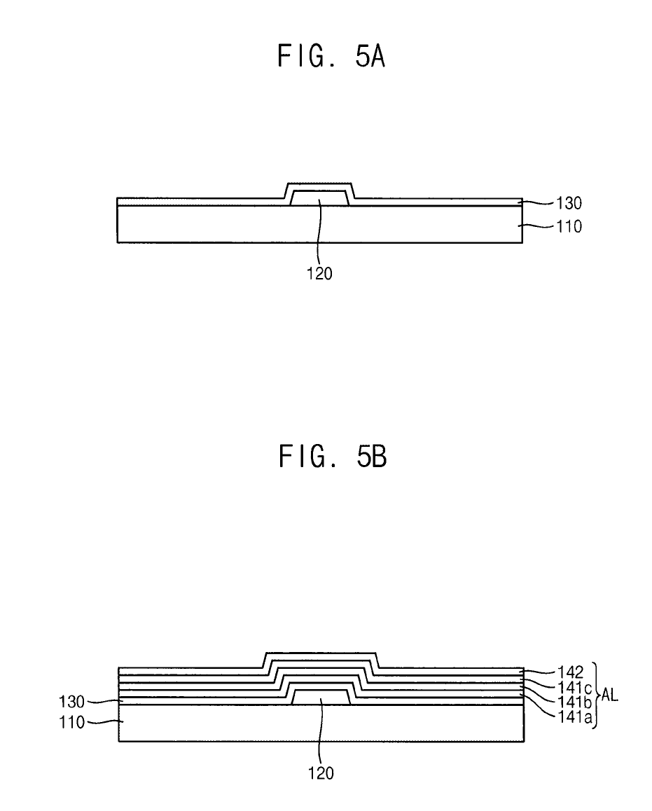

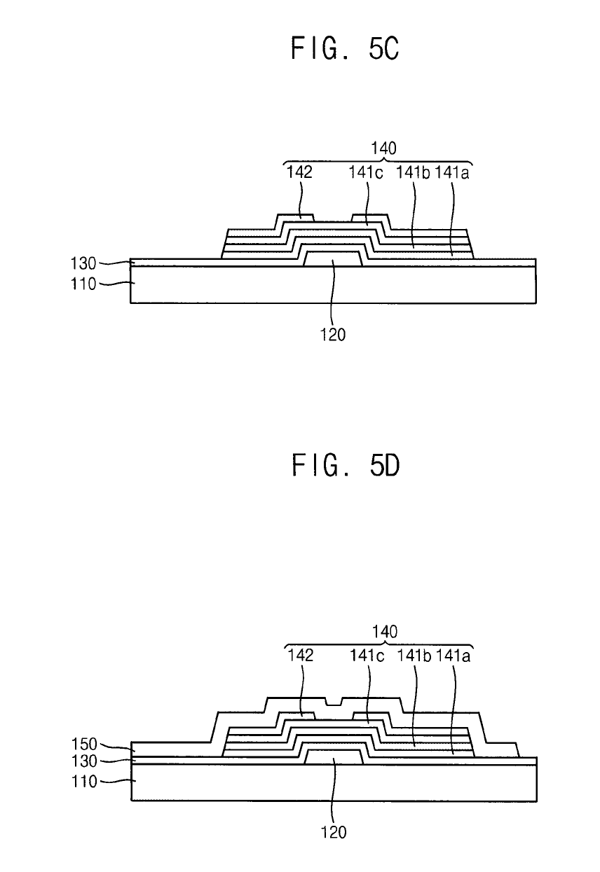

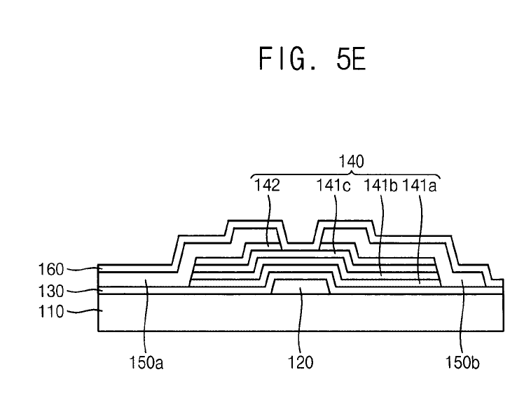

FIGS. 5A, 5B, 5C, 5D and 5E are cross-sectional views for describing a method of manufacturing a display substrate according to example embodiments.

Referring to FIG. 5A, the gate pattern may be formed on the base substrate 110. The gate pattern may include the gate electrode 120.

The gate pattern may include a low resistance material. For example, the gate pattern may include at least one selected from the group consisting of aluminum (Al), molybdenum (Mo), titanium (Ti), copper (Cu) and an alloy thereof The gate pattern may be formed in a single layer or a multi layer.

The insulation layer 130 may be formed on the base substrate 110 on which the gate pattern is formed. The gate pattern may be insulated by the insulation layer 130.

The insulation layer 130 may include inorganic insulation material. For example, the insulation layer 130 may include at least one selected from the group consisting of silicon oxide (SiO_{X}) and silicon nitride (SiN_{X}). For example, the insulation layer 130 may be formed by a sputtering process.

Referring to FIG. 5B, an active layer AL may be formed on the base substrate 110 on which the gate pattern and the insulation layer 130 are formed. The active layer AL may include amorphous silicon (a-Si:H).

The active layer AL may include the first active layer 141a, the second active layer 141b and the third active layer 141c. The active layer AL may further include the ohmic contact layer 142. For example, the active layer AL may be formed by sequentially depositing the first active layer 141a, the second active layer 141b, the third active layer 141c and the ohmic contact layer 142 on the base substrate 110 on which the gate pattern is formed. The ohmic contact layer 142 may be omitted depending on a material used as the source electrode 150a and the drain electrode 150b.

The first active layer 141a may be formed on the base substrate 110 on which the gate pattern is formed and may include the first amorphous silicon. The first amorphous silicon in the first active layer 141a may include Si—H bond.

The first active layer 141a may be formed by a deposition process based on a mixed gas including silane (Si) and hydrogen (H₂). A volume ratio of silane and hydrogen in the mixed gas may be about 1:4 to about 1:5. If the volume ratio of silane and hydrogen in the mixed gas is less than about 1:4 (e.g., if a volume of hydrogen in the mixed gas is under four times more than a volume of silane in the mixed gas), the silicon dangling bonds in the first active layer 141a may increase due to lack of the Si—H bond. If the volume ratio of silane and hydrogen in the mixed gas is more than about 1:5 (e.g., if the volume of hydrogen in the mixed gas is over five times more than the volume of silane in the mixed gas), the silicon dangling bonds in the first active layer 141a may increase due to increasing of the Si—H₂ bond.

In some example embodiments, the first active layer 141a may have a thickness of about 100 Å to about 150 Å. If the first active layer 141a has a thickness of less than about 100 Å, it may be difficult to reduce a leakage current from the active pattern 140. If the first active layer 141a has a thickness of more than about 150 Å, a deposition rate of the first active layer 141a may decrease, and manufacturing costs may increase.

In some example embodiments, the first active layer 141a may have a deposition rate of about 5 Å/sec to about 6 Å/sec. If the deposition rate for forming the first active layer 141a is less than about 5 Å/sec, manufacturing time may increase. If the deposition rate for forming the first active layer 141a is more than about 6 Å/sec, the silicon dangling bonds in the first active layer 141a may increase due to increasing of the Si—H₂ bond.

The second active layer 141b may be formed on the first active layer 141a and may include the second amorphous silicon of which the concentration of hydrogen is higher than that of the first amorphous silicon. The second amorphous silicon in the second active layer 141b may include Si—H bond and Si—H₂ bond.

In some example embodiments, the amount of the Si—H₂ bond in the second active layer 141b may be about 5 mol % to about 10 mol % of total mol of the Si—H bond and the Si—H₂ bond.

The second active layer 141b may be formed using a mixed gas including silane (Si) and hydrogen (H₂). A volume ratio of silane and hydrogen in the mixed gas may be about 1:6 to about 1:7. If the volume ratio of silane and hydrogen in the mixed gas is less than about 1:6 (e.g., if a volume of hydrogen in the mixed gas is under six times more than a volume of silane in the mixed gas), the silicon dangling bonds in the second active layer 141b may increase due to lack of the Si—H bond. If the volume ratio of silane and hydrogen in the mixed gas is more than about 1:7 (e.g., if the volume of hydrogen in the mixed gas is over seven times more than the volume of silane in the mixed gas), the silicon dangling bonds in the second active layer 141b may increase due to increasing of the Si—H₂ bond.

In addition, the volume of the mixed gas for forming the second active layer 141b may be about three to five times more than the volume of the mixed gas for forming the first active layer 141a. Thus, manufacturing time may decrease by increasing the deposition rate of the second active layer 141b.

In some example embodiments, the second active layer 141b may have a thickness of about 1000 Åto about 1500 Å. If the second active layer 141b has a thickness of less than about 1000 Å, a deposition rate of the second active layer 141b may decrease, and manufacturing costs may increase. If the second active layer 141b has a thickness of more than about 1500 Å, it may be difficult to reduce a leakage current from the active pattern 140.

In some example embodiments, the second active layer 141b may be formed of deposition rate of about 20 Å/sec to about 30 Å/sec. If the deposition rate of the second active layer 141b is less than about 20 Å/sec, manufacturing time may increase. If the deposition rate of the second active layer 141b is more than about 30 Å/sec, the silicon dangling bonds in the second active layer 141b may increase due to increasing of the Si—H₂ bond.

The third active layer 141c may be formed on the second active layer 141b and may include the third amorphous silicon of which the concentration of hydrogen is substantially the same as that of the first amorphous silicon.

The third active layer 141c may be formed using a mixed gas including silane (Si) and hydrogen (H₂). A volume ratio of silane and hydrogen in the mixed gas may be about 1:4 to about 1:5. If the volume ratio of silane and hydrogen in the mixed gas is less than about 1:4 (e.g., if a volume of hydrogen in the mixed gas is under four times more than a volume of silane in the mixed gas), the silicon dangling bonds in the third active layer 141c may increase due to lack of the Si—H bond. If the volume ratio of silane and hydrogen in the mixed gas is more than about 1:5 (e.g., if the volume of hydrogen in the mixed gas is over five times more than the volume of silane in the mixed gas), the silicon dangling bonds in the third active layer 141c may increase due to increasing of the Si—H₂ bond.

In some example embodiments, the third active layer 141c may have a thickness of about 300 Å to about 500 Å. If the third active layer 141c has a thickness of less than about 300 Å, it may be difficult to reduce a leakage current from the active pattern 140. If the third active layer 141c has a thickness of more than about 500 Å, a deposition rate of the third active layer 141c may decrease, and manufacturing costs may increase.

In some example embodiments, the third active layer 141c may be formed of a deposition rate of about 5 Å/sec to about 6 Å/sec. If the deposition rate of the third active layer 141c is less than about 5 Å/sec, manufacturing time may increase. If the deposition rate of the third active layer 141c is more than about 6 Å/sec, the silicon dangling bonds in the third active layer 141c may increase due to increasing of the Si—H₂ bond.

The ohmic contact layer 142 may be formed on the third active layer 141c and may include impurity-doped silicon. For example, the impurity-doped silicon may include phosphorous.

Referring to FIG. 5C, the active pattern 140 may be formed by patterning the active layer AL.

Although not illustrated in FIG. 5C, photoresist material may be coated on the active layer AL, and thus a photoresist layer may be formed on the active layer AL. The photoresist layer may be exposed to light using a mask and a portion of the photo resist layer may be developed to form a photoresist pattern on a position where the active pattern 140 is to be formed. For example, the mask may be a halftone mask. The photoresist pattern may have a first thickness on which the ohmic contact layer 142 is formed and a second thickness less than the first thickness on which the ohmic contact layer 142 is removed. To form the first and second ohmic contact layers that are spaced apart from each other on the third active layer 141c, the photoresist pattern between the first and second ohmic contact layers may have the second thickness. An exposed portion of the active layer AL may be removed using the photoresist pattern as a mask to form an active layer pattern. The photoresist pattern may be partially removed by ashing to expose the active layer AL on a channel area. The ohmic contact layer on the channel area may be selectively removed by using the ashed photo resist layer as a mask.

Referring to FIGS. 5D and 5E, a data metal layer 150 may be formed on the insulation layer 130 on which the active pattern 140 is disposed. The data metal layer 150 may be formed on the whole of the base substrate 110.

Although not illustrated in FIGS. 5D and 5E, photoresist material may be coated on the data metal layer 150, and thus a photoresist layer may be formed on the data metal layer 150. The photoresist layer may be exposed to light using a mask and may be developed, and thus photoresist patterns may be formed on positions where the data line DL, the source electrode 150a and the drain electrode 150b are to be formed. An exposed portion of the data metal layer 150 may be removed using the photoresist patterns as a mask, the photoresist patterns may be removed, and thus the data metal pattern including the source electrode 150a and the drain electrode 150b may be formed.

The gate electrode 120, the source electrode 150a, the drain electrode 150b and the active pattern 140 may form the thin film transistor TFT.

The passivation layer 160 may be disposed on the insulation layer 130 on which the active pattern 140 and the data metal pattern are disposed. The source electrode 150a, the drain electrode 150b and the active pattern 140 may be insulated by the passivation layer 160.

The passivation layer 160 may include inorganic insulation material. For example, the passivation layer 160 may include at least one selected from the group consisting of silicon oxide (SiO_{X}) and silicon nitride (SiN_{X}). For example, the passivation layer 160 may be formed by a sputtering process.

The color filter 170 may be formed on the passivation layer 160. The contact hole CNT may be formed in the color filter 170 to expose a portion of the drain electrode 150b. The pixel electrode PE may be formed on the color filter 170 and may be electrically connected to the drain electrode 150b of the thin film transistor TFT through the contact hole CNT.

The above described embodiments may be used in a display apparatus including a thin film transistor and/or a system including the display apparatus, such as a LCD apparatus, an OLED apparatus, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A display substrate comprising:
a base substrate;
a gate pattern comprising a gate electrode on the base substrate;
an active pattern overlapping the gate electrode, the active pattern comprising:
a first active layer comprising first amorphous silicon (a-Si:H);
a second active layer on the first active layer, the second active layer including second amorphous silicon of which a concentration of hydrogen is higher than that of the first amorphous silicon; and
a third active layer on the second active layer, the third active layer including third amorphous silicon of which a concentration of hydrogen is substantially lower than that of the second active layer ; and
a data metal pattern on the active pattern, the data metal pattern comprising source and drain electrodes spaced apart from each other.

2. The display substrate of claim 1, wherein the third active layer is substantially the same as the first active layer.

3. The display substrate of claim 1, wherein the first amorphous silicon in the first active layer includes Si—H bond.

4. The display substrate of claim 3, wherein the second amorphous silicon in the second active layer includes the Si—H bond and Si—H₂ bond.

5. The display substrate of claim 4, wherein an amount of the Si—H₂ bond in the second active layer is about 5 mol % to about 10 mol % of a total mol % of the Si—H bond and the Si—H₂ bond.

6. The display substrate of claim 1, wherein the first active layer has a thickness of about 100 Å to about 150 Å.

7. The display substrate of claim 1, wherein the second active layer has a thickness of about 1000 Å to about 1500 Å.

8. The display substrate of claim 1, wherein the third active layer has a thickness of about 300 Å to about 500 Å.

9. The display substrate of claim 1, further comprising:
an ohmic contact layer on the third active layer and comprising impurity-doped silicon.

10. The display substrate of claim 9, wherein the impurity-doped silicon includes phosphorous.

11. A method of manufacturing a display substrate, the method comprising:
forming a gate pattern on a base substrate, the gate pattern comprising a gate electrode;
forming an active layer by sequentially depositing a first active layer, a second active layer and a third active layer on the base substrate on which the gate pattern is formed, wherein the first active layer includes first amorphous silicon (a-Si:H), the second active layer includes second amorphous silicon of which a concentration of hydrogen is higher than that of the first amorphous silicon, and the third active layer includes third amorphous silicon of which a concentration of hydrogen is substantially lower than that of the second active layer; and
forming an active pattern by patterning the active layer.

12. The method of claim 11, wherein the third active layer is substantially the same as the first active layer.

13. The method of claim 11, wherein the first active layer and the third active layer are formed by a deposition process using a mixed gas including silane (Si) and hydrogen (H₂), and
a volume ratio of silane and hydrogen in the mixed gas is about 1:4 to about 1:5.

14. The method of claim 13, wherein the first active layer has a thickness of about 100 Å to about 150 Å, and the third active layer has a thickness of about 300 Å to about 500 Å.

15. The method of claim 14, wherein the first active layer and the third active layer have a deposition rate of about 5 Å/sec to about 6 Å/sec.

16. The method of claim 11, wherein the second active layer is formed by a deposition process using a mixed gas including silane (Si) and hydrogen (H₂), and
a volume ratio of silane and hydrogen in the mixed gas is about 1:6 to about 1:7.

17. The method of claim 16, wherein the second amorphous silicon in the second active layer includes Si—H bond and Si—H₂ bond, and an amount of the Si—H₂ bond in the second active layer is about 5 mol % to about 10 mol % of a total mol % of the Si—H bond and the Si—H₂ bond.

18. The method of claim 16, wherein the second active layer has a thickness of about 1000 Å to about 1500 Å.

19. The method of claim 16, wherein the second active layer has a deposition rate of about 20 Å/sec to about 30 Å/sec.

20. The method of claim 11, further comprising:
forming an ohmic contact layer comprising impurity-doped silicon on the third active layer.
